(19) United States
(12) Patent Application Publication
(10) Pub. No.: US 2015/0282306 A1
(43) Pub. Date: Oct. 1, 2015

(54) MULTILAYER SUBSTRATE STRUCTURE FOR FINE LINE

(71) Applicant: KINSUS INTERCONNECT TECHNOLOGY CORP., Taoyuan (TW)

(72) Inventors: Ting-Hao Lin, Taipei (TW); Yu-Te Lu, Taoyuan Hsien (TW)

(73) Assignee: KINSUS INTERCONNECT TECHNOLOGY CORP., Taoyuan (TW)

(21) Appl. No.: 14/225,671

(22) Filed: Mar. 26, 2014

(51) Int. Cl. H05K 1/02; H05K 1/11; H05K 1/09

(52) U.S. Cl. CPC H05K 1/0298; H05K 1/09; H05K 1/112; H05K 2201/0195

(57) ABSTRACT

A multilayer substrate structure includes a first plastic sheet, a second plastic sheet, a first circuit pattern layer, a second circuit pattern layer, and an interlayer connection pad. A first connection plug connected to the interlayer connection pad fills in a first opening of a first plastic sheet and is connected to a first connection pad of the first circuit pattern layer. A second connection plug fills a second opening of the second plastic sheet and is connected to a second connection pad of the second circuit pattern layer such that the second circuit pattern layer is electrically connected to the first circuit pattern layer via the interlayer connection pad. Therefore, even if there is little offset, it is possible to overcome the alignment tolerance and assure electrical connection between the circuit layers as desired.

### BACKGROUND OF THE INVENTION

1. Field of the Invention

The present invention generally relates to a multilayer substrate structure, and more specifically to a multilayer substrate structure for fine line having plastic sheets and interlayer connection pads provided between adjacent circuit layers to overcome alignment tolerance and improve the yield rate of products.

2. The Prior Arts

FIGS. 1A to 1D schematically illustrate the successive steps of manufacturing a multilayer substrate structure in the prior arts, respectively. As shown in FIG. 1A, a substrate 10 is provided with two seed layers 20 on the upper and lower surfaces by electroplating, respectively, and two patterned photo resist layers 200 are then formed on the two seed layers 20, respectively. Next in FIG. 1B, a first circuit pattern layer 30 and a second circuit pattern layer 32 are formed at the openings of the surfaces of the two patterned photo resist layers 200, respectively. The first circuit pattern layer 30 includes a first circuit pattern 31 and a first connection pad 33, and similarly the second circuit pattern layer 32 includes a second circuit pattern 37 and a second connection pad 39. The second connection pad 39 has a shape of a ring with a central region 40. In FIG. 1C, the patterned photo resist layers 200 and the seed layers 20 are removed, and an opening 100 is formed by drilling the central region 40 of the second connection pad 39. Specifically, the opening 100 stops at the first connection pad 33. Further referring to FIG. 1D, the opening 100 and the central region 40 are filled with metal by electroplating such that the first circuit pattern 31 is electrically connected to the second circuit pattern layer 32. Finally, a first solder mask 51 and a second solder mask 53 are formed on the upper surfaces of the first circuit pattern layer 30 and the second circuit pattern layer 32, respectively. The first solder mask 51 covers most of the first circuit pattern 31 and part of the first connection pad 33, and the second solder mask 53 covers most of the second circuit pattern 37 and part of the second connection pad 39. One shortcoming of the above example in the prior arts is that the seed layers 20 are located on the first circuit pattern 31 and the second circuit pattern layer 32, and the seed layers 20 is removed by etching. As a result, part of the first circuit pattern 31 and the second circuit pattern layer 32 are possibly removed at the same time, and it is thus needed to increase the width of the first circuit pattern 31 and second circuit pattern layer 32 with specific width for circuit compensation. Traditionally, the thickness of the seed layers 20 is about 1 to 2 μm, and the typical width and pitch for the present technology are about 10 μm such that the loss due to etching is up to 20 to 40%, resulting in challenging bottleneck in technology.

For another example in the prior arts, please refer to FIGS. 2A to 2D illustrating the steps of manufacturing the multilayer substrate structure, respectively. The present example is intended to improve the circuit compensation for etching in the first example so as to implement much finer line and achieve much denser circuitry. As shown in FIG. 2A, two steel plates 500 and a plastic sheet 12 are prepared. Each steel plates 500 is provided with a seed layer 20 by electroplating, and a first circuit pattern layer 30 and a second circuit pattern layer 32 are formed by the image transfer process, respectively. Then in FIG. 2B, the two steel plates 500 and the plastic sheet 12 are pressed together so as to embed the first circuit pattern layer 30 and the second circuit pattern layer 32 into the plastic sheet 12. The two steel plates 500 and the seed layers 20 are removed. The steps shown in FIGS. 2C and 2D are similar to the first example. A first opening 100 is formed by drilling, and then filled with metal by electroplating to form a first solder mask 51 and a second solder mask 53. The seed layers 20 are located on the upper and lower surfaces after removing the steel plates 500 such that the first circuit pattern layer 30 and the second circuit pattern layer 32 are not affected during the step of removing. Therefore, it is no need to design larger width for circuit compensation.

However, the actual situation is possibly like what FIGS. 2B′ and 2C′ show. Because of certain tolerance of the machine used in the step of pressing, typically about 40 to 100 μm, the position of the circuit while pressed is possibly what FIG. 2B shows. That is, the first circuit pattern layer 30 and the second circuit pattern layer 32 obviously deviate from the preset position. Therefore, it is possible to penetrate the plastic sheet 12 while drilling by laser, if the first connection pad 33 and the second connection pad 39 are offset too much. Owing to the alignment tolerance larger than the width, it needs a multilayer substrate structure without circuit compensation to overcome the drawbacks in the prior arts.

### SUMMARY OF THE INVENTION

The primary object of the present invention is to provide a multilayer substrate structure for fine line, which includes a first plastic sheet, a second plastic sheet, a first circuit pattern layer, a second circuit pattern layer and at least one interlayer connection pad. The first circuit pattern layer is embedded in an upper surface of the first plastic sheet, and the surface of the first circuit pattern layer is exposed to an exterior of the first plastic sheet. The first circuit pattern layer includes a first circuit pattern and at least one first connection pad. The first plastic sheet has a lower surface formed with a first opening in alignment with the first connection pad. The first opening is filled with an electrically conductive material to form a first connection plug, which is connected to the first connection pad. Moreover, the interlayer connection pad is formed on the lower surface of the first plastic sheet, is connected to the first connection plug, and has a width of 40 to 100 μm.

The upper surface of the second plastic sheet is connected to the lower surface of the first plastic sheet. The interlayer connection pad is embedded in the lower surface of the second plastic sheet. The surface of the second circuit pattern layer is exposed to the second plastic sheet. The second circuit pattern layer includes a second circuit pattern and at least one second connection pad. A second opening is formed on the second plastic sheet, and is filled with the electrically conductive material to form the second connection plug, which is connected to the interlayer connection pad. Therefore, the second circuit pattern layer is electrically connected to the first circuit pattern layer via the first connection plug, the interlayer connection pad and the second connection plug.

The multilayer substrate structure for fine line further includes a third plastic sheet, a fourth plastic sheet, a fifth plastic sheet, a sixth plastic sheet, a third circuit pattern layer, a fourth circuit pattern layer, at least one second interlayer connection pad, at least one third interlayer connection pad, at least one third connection plug, at least one fourth connection plug, at least one fifth connection plug, and at least one sixth connection plug which are stacked on the first and second plastic sheets to form a multilayer structure.

The lower surface of the third plastic sheet is connected to the upper surface of the first plastic sheet, and at least one third opening is formed through the third plastic sheet and is aligned with the first connection pad, and is filled with the electrically conductive material to form a third connection plug. The second interlayer connection pad is formed on the upper surface of the third plastic sheet and is connected to the third connection plug. Symmetrically, the upper surface of the fourth plastic sheet is connected to the lower surface of the second plastic sheet. At least one fourth opening is formed through the fourth plastic sheet and is aligned with the second connection pad, and is filled with the electrically conductive material to form the forth connection plug. The third interlayer connection pad is provided on the lower surface of the forth plastic sheet and connected to the fourth connection plug.

The lower surface of the fifth plastic sheet is connected to the upper surface of the third plastic sheet. The third circuit pattern layer is embedded in the upper surface of the fifth plastic sheet, and includes a third circuit pattern and at least one third connection pad. A fifth opening is formed through the center of the third connection pad and is aligned with the second interlayer connection pad, and is filled with the electrically conductive material to form the fifth connection plug. Symmetrically, the upper surface of the sixth plastic sheet is connected to the lower surface of the fourth plastic sheet. The fourth circuit pattern layer is embedded in the lower surface of the sixth plastic sheet, and includes a fourth circuit pattern and at least one fourth connection pad in form of annular. A sixth opening is formed through the center of the fourth connection pad and is aligned with the third interlayer connection pad, and is filled with the electrically conductive material to form the sixth connection plug.

According to one feature of the present invention, two circuit pattern layers are not directly stacked in the same plastic sheet, but provided on two plastic sheets, respectively, and separated by one interlayer connection pad which outwardly extends and is laterally larger in size. Therefore, it is possible to easily overcome the alignment tolerance, and assure electrical connection between the circuit layers as desired. Especially, the problem that the plastic sheet suffers damage due to forming the opening by drilling is solved so as to improve the whole yield of the multilayer substrate structure for fine line.

### BRIEF DESCRIPTION OF THE DRAWINGS

The present invention can be understood in more detail by reading the subsequent detailed description in conjunction with the examples and references made to the accompanying drawings, wherein:

The present invention can be understood in more detail by reading the subsequent detailed description in conjunction with the examples and references made to the accompanying drawings, wherein:

FIGS. 1A to 1D are cross sectional views illustrating the steps of manufacturing the multilayer substrate structure in the prior arts, respectively;

FIGS. 2A to 2D are cross sectional views illustrating the steps of manufacturing the multilayer substrate structure in another example of the prior arts, respectively;

FIGS. 2B′ to 2C′ are cross sectional views showing the actual situation in the prior arts, respectively;

FIG. 3 is a view schematically showing the first embodiment of a multilayer substrate structure for fine line according to the present invention; and

FIG. 4 is a view schematically showing the second embodiment of the multilayer substrate structure for fine line according to the present invention.

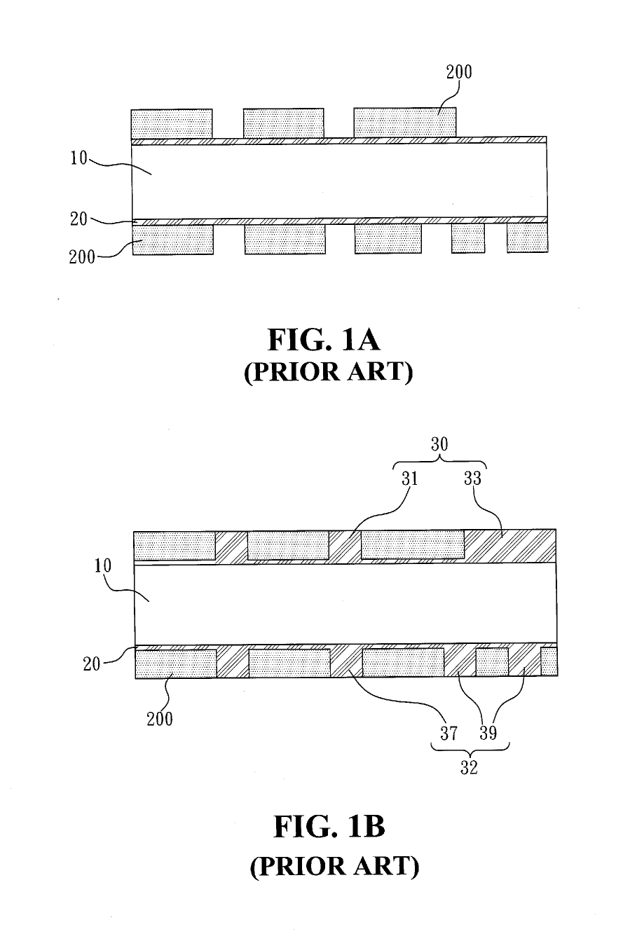

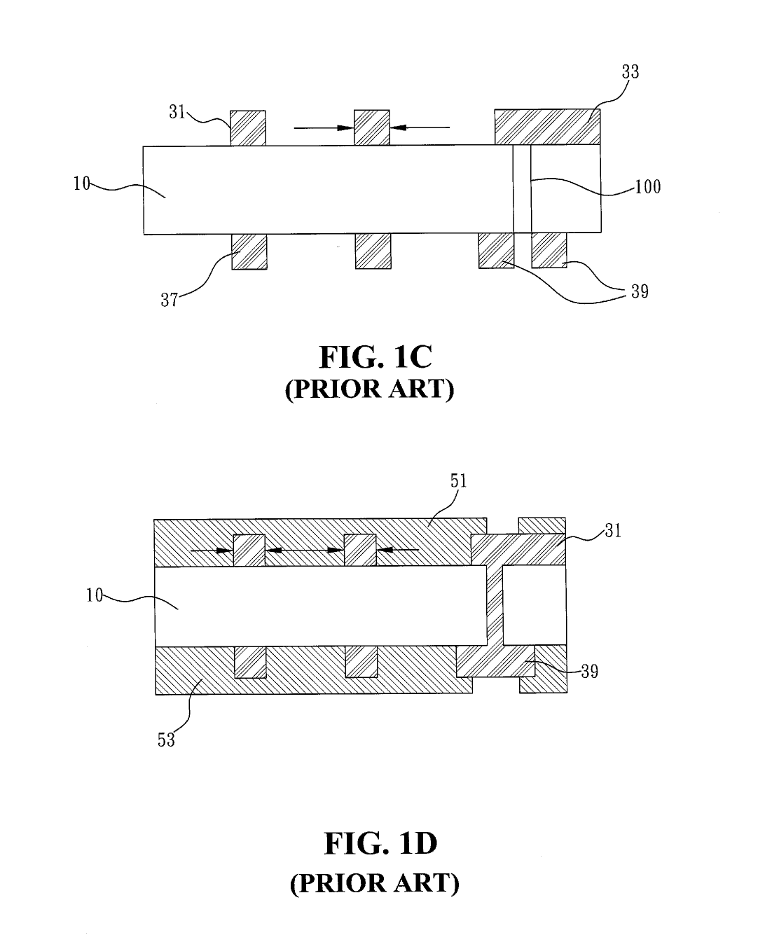

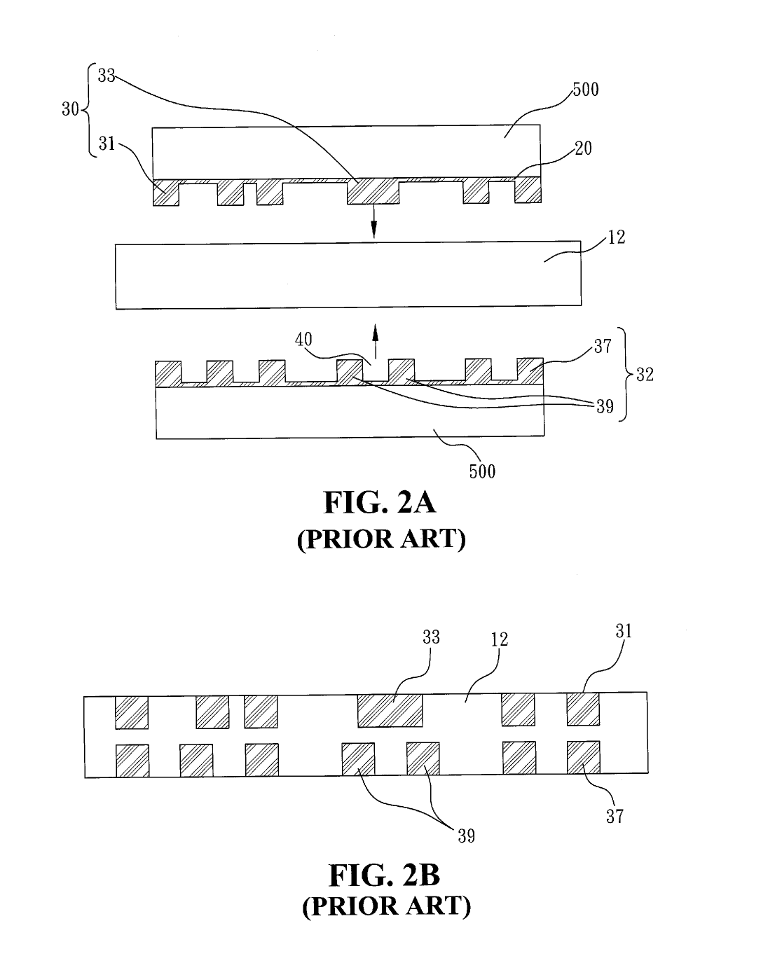

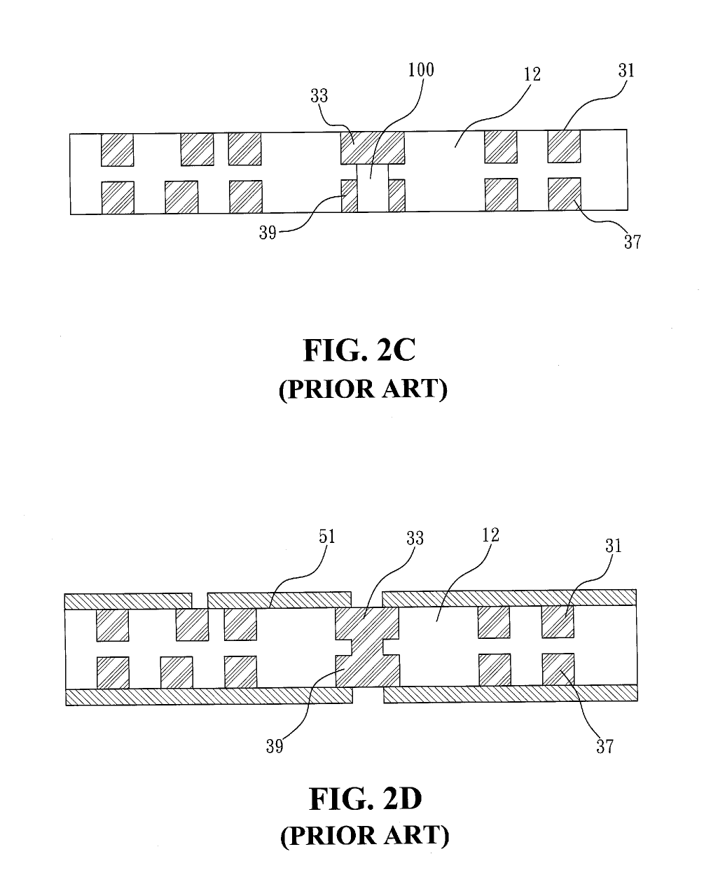

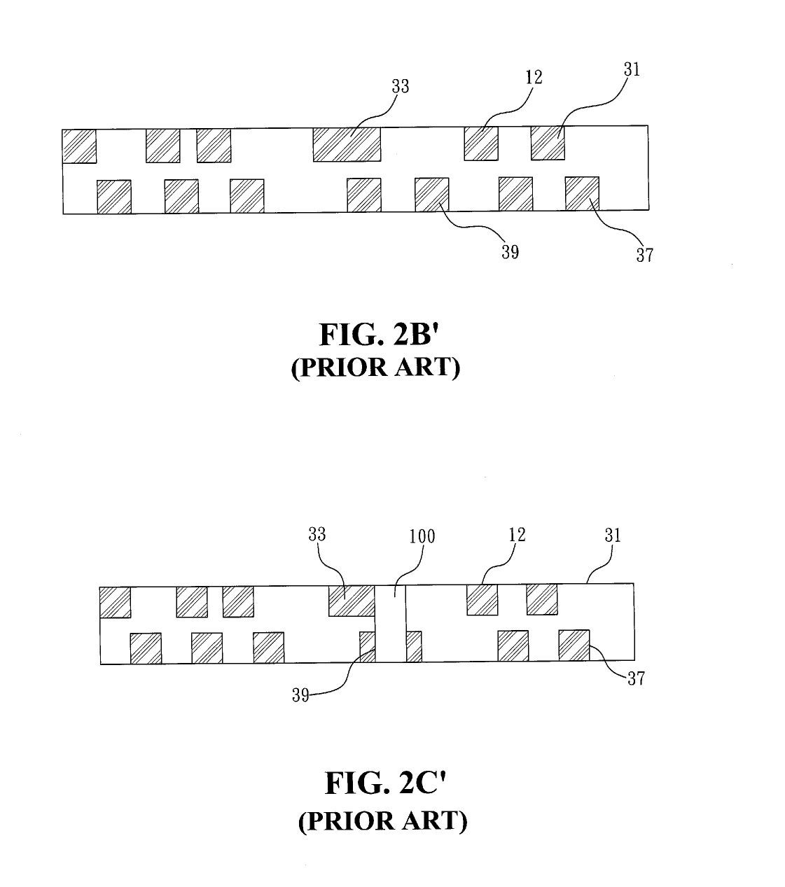

### DETAILED DESCRIPTION OF THE PREFERRED EMBODIMENTS

The present invention may be embodied in various forms and the details of the preferred embodiments of the present invention will be described in the subsequent content with reference to the accompanying drawings. The drawings (not to scale) show and depict only the preferred embodiments of the invention and shall not be considered as limitations to the scope of the present invention. Modifications of the shape of the present invention shall too be considered to be within the spirit of the present invention.

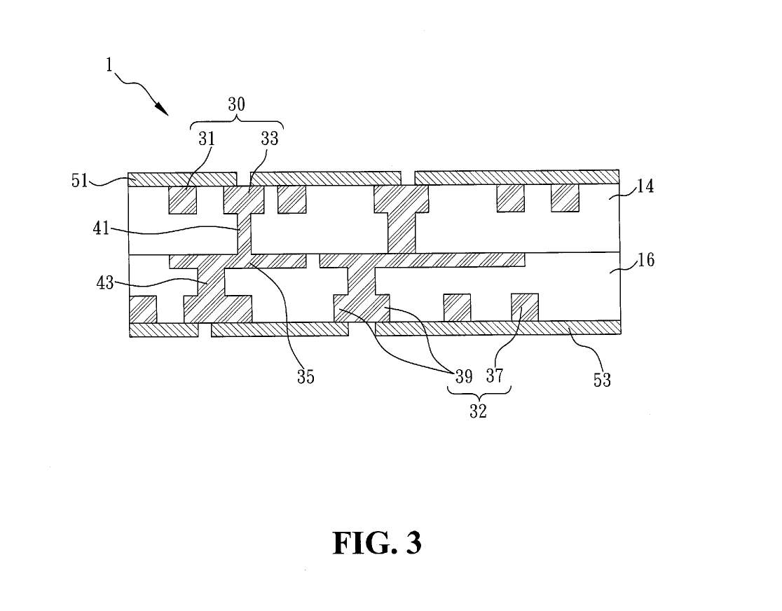

FIG. 3 schematically shows the first embodiment of the multilayer substrate structure for fine line according to the present invention. As shown in FIG. 3, the multilayer substrate structure 1 for fine line according to present invention generally includes a first plastic sheet 14, a second plastic sheet 16, a first circuit pattern layer 30, a second circuit pattern layer 32, at least one first connection plug 41, at least one second connection plug 43, at least one interlayer connection pad 35, a first solder mask 51 and a second solder mask 53.

The first circuit pattern layer 30 is embedded in an upper surface of the first plastic sheet 14 in such a manner that the surface of the first circuit pattern layer 30 is exposed to an exterior of the first plastic sheet 14. The first circuit pattern layer 30 includes a first circuit pattern 31 and a first connection pad 33. The first plastic sheet 14 has a lower surface formed with a first opening in alignment with the first connection pad 33, and is filled with an electrically conductive material to form the first connection plug 41, which is thus connected to the first connection pad 33. The interlayer connection pad 35 is made from the electrically conductive material, is provided on the lower surface of the first plastic sheet 14, and is connected to the first connection plug 41. In particular, the interlayer connection pad 35 has a width of 40 to 100 μm.

The interlayer connection pad 35 is embedded in an upper surface of the second plastic sheet 16, which is connected to the lower surface of the first plastic sheet 14. The second circuit pattern layer 32 is embedded in the lower surface of the second plastic sheet 16, which exposes the lower surface of the second circuit pattern layer 32. Moreover, the second circuit pattern layer 32 includes a second circuit pattern 37 and a second connection pad 39. Specifically, the second connection pad 39 has a shape of a ring which has a central region. A second opening formed through the second plastic sheet 16 stops at the interlayer connection pad 35, and is filled with the electrically conductive material to form the second connection plug 43, which is thus connected to the second connection pad 39 and the interlayer connection pad 35.

The first solder mask 51 is provided on the upper surface of the first plastic sheet 14, and covers the first circuit pattern 31 and part of the first connection pad 33. Similarly, the second solder mask 53 is provided on the lower surface of the second plastic sheet 14, and covers the second circuit pattern 37 and part of the second connection pad 39.

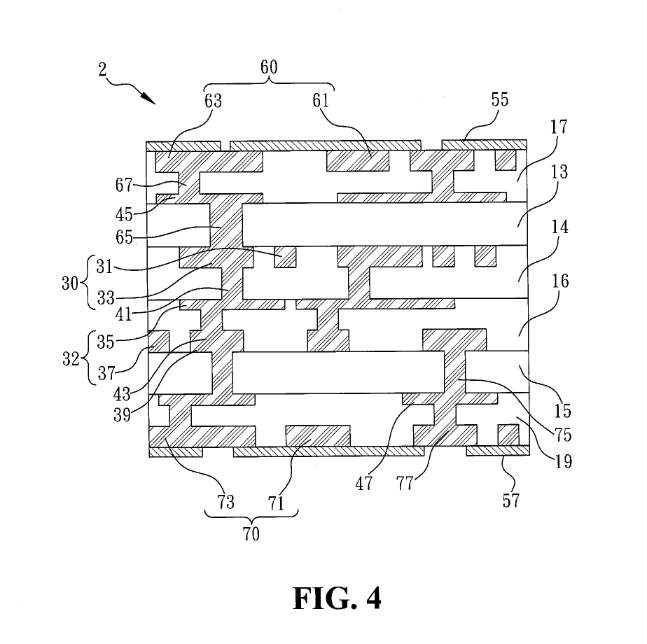

Additionally, FIG. 4 illustrates a cross sectional view of the second embodiment of the multilayer substrate structure for fine line according to the present invention. The second embodiment is substantially similar to the above first embodiment in structure, and one of the primary differences is that the multilayer substrate structure of the second embodiment further includes another interlayer connection pad stacked on the upper surface of the first plastic sheet 14, and another circuit pattern layer stacked on the lower surface of the second plastic sheet 16. As shown in FIG. 4, the multilayer substrate structure 2 of the second embodiment generally includes a first plastic sheet 14, a second plastic sheet 16, a third plastic sheet 13, a fourth plastic sheet 15, a fifth plastic sheet 15, a sixth plastic sheet 15, a first circuit pattern layer 30, a second circuit pattern layer 32, a third circuit pattern layer 60, a fourth circuit pattern layer 70, at least one interlayer connection pad 35, at least one second interlayer connection pad 65, at least one third interlayer connection pad 75, at least one first connection plug 41, at least one second connection plug 43, at least one second interlayer connection pad 45, at least one third interlayer connection pad 45, at least one third connection plug 65, at least one fourth connection plug 75, at least one fifth connection plug 65, and at least one sixth connection plug 77.

The lower surface of the third plastic sheet 13 is connected to the upper surface of the first plastic sheet 14. At least one third opening is formed through the third plastic sheet 13 and is aligned with the first connection pad 33, and is filled with the electrically conductive material to form the third connection plug 65. The second interlayer connection pad 45 is provided on the upper surface of the third plastic sheet 13 and connected to the third connection plug 65. Symmetrically, the upper surface of the fourth plastic sheet 15 is connected to the lower surface of the second plastic sheet 16. At least one fourth opening is formed through the fourth plastic sheet 15 and is aligned with the second connection pad 39, and is filled with the electrically conductive material to form the forth connection plug 75. The third interlayer connection pad 47 is provided on the lower surface of the forth plastic sheet 15 and connected to the fourth connection plug 75.

The lower surface of the fifth plastic sheet 17 is connected to the upper surface of the third plastic sheet 13. The third circuit pattern layer 60 is embedded in the upper surface of the fifth plastic sheet 17, and includes a third circuit pattern 61 and at least one third connection pad 63 in form of annular. A fifth opening is formed through the center of the third connection pad 63 and is aligned with the second interlayer connection pad 45, and is filled with the electrically conductive material to form the fifth connection plug 67. Symmetrically, the upper surface of the sixth plastic sheet 19 is connected to the lower surface of the fourth plastic sheet 15. The fourth circuit pattern layer 70 is embedded in the lower surface of the sixth plastic sheet 19, and includes a fourth circuit pattern 71 and at least one fourth connection pad 73 in form of annular. A sixth opening is formed through the center of the fourth connection pad 73 and is aligned with the third interlayer connection pad 47, and is filled with the electrically conductive material to form the sixth connection plug 77. Specifically, each of the second interlayer connection pad 65 and the third interlayer connection pad 75 has a width of 40 to 100 μm.

The multilayer substrate structure 2 of the second embodiment further includes a third solder mask 55 and a fourth solder mask 57. The third solder mask 55 is provided on the upper surface of the fifth plastic sheet 17, and covers the third circuit pattern 61 and part of the third connection pad 63. The fourth solder mask 57 is provided on the lower surface of the sixth plastic sheet 19, and covers the fourth circuit pattern 71 and part of the fourth connection pad 73.

It should be noted that the above-mentioned multilayer substrate structure 2 which shows only two additional layers stacked on the upper and lower surfaces of the first embodiment, respectively, is not intended to limit the scope of the present invention. In general, the present invention is to provide a specific structure which has the interlayer connection pad and the plastic sheet between two circuit pattern layers. More specifically, the electrically conductive material may comprise at least one of gold, silver, copper, aluminum, nickel and palladium.

One feature of the present invention is that two circuit pattern layers are not directly stacked in the same plastic sheet, but the two circuit pattern layers are provided on two plastic sheets, respectively, and separated by one interlayer connection pad which outwardly extends and is laterally larger in size. Therefore, it is possible to easily overcome the alignment tolerance, and assure electrical connection between the circuit layers as desired. In particular, the problem that the plastic sheet suffers damage due to forming the opening by drilling is solved so as to improve the whole yield of the multilayer substrate structure for fine line.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A multilayer substrate structure for fine line, comprising:
a first plastic sheet;
a first circuit pattern layer embedded in an upper surface of the first plastic sheet in such a manner that a surface of the first circuit pattern layer is exposed from the upper surface of the first plastic sheet, the first circuit pattern layer including a first circuit pattern and at least one first connection pad, the first plastic sheet having a lower surface formed with a first opening in alignment with the first connection pad;
at least one first connection plug made from an electrically conductive material, wherein the first connection plug fills in the first opening so as to connect with the first connection pad;
at least one interlayer connection pad located on the lower surface of the first plastic sheet and made from the electrically conductive material, wherein the interlayer connection pad is connected to the first connection plug;
a second plastic sheet having an upper surface connected to the lower surface of the first plastic sheet, wherein the interlayer connection pad is embedded in the second plastic sheet;
a second circuit pattern layer embedded in a lower surface of the second plastic sheet and having a surface exposed to the lower surface of the second plastic sheet, wherein the second circuit pattern layer includes a second circuit pattern and at least one second connection pad, the second connection pad having a shape of a ring with a central region, the second plastic sheet having a second opening in alignment with the central region of the second connection pad; and
at least one second connection plug made from the electrically conductive material, wherein the second connection plug fills the second opening in such a manner to connected the interlayer connection pad,
wherein the interlayer connection pad has a width of 40 to 100 μm.

2. The multilayer substrate structure as claimed in claim 1, further comprising a first solder mask and a second solder mask, wherein the first solder mask is provided on the upper surface of the first plastic sheet to cover the first circuit pattern and part of the first connection pad, and the second solder mask is provided on the lower surface of the second plastic sheet to cover the second circuit pattern and part of the second connection pad.

3. The multilayer substrate structure as claimed in claim 1, wherein the electrically conductive material consists of at least one of gold, silver, copper, aluminum, nickel and palladium.

4. The multilayer substrate structure as claimed in claim 1, further comprising:
a third plastic sheet having a lower surface connected to the upper surface of the first plastic sheet,
at least one third connection plug made from of the electrically conductive material, wherein the third connection plug fills the third opening in such a manner to connected with the first connection pad;
at least one second interlayer connection pad located on the upper surface of the third plastic sheet, and connected to the corresponding third connection plug;
a fourth plastic sheet having an upper surface connected to the lower surface of the second plastic sheet;
at least one fourth connection plug made from the electrically conductive material, wherein the fourth connection plug fills the fourth opening in such a manner to connected with the second connection pad;
at least one third interlayer connection pad located on the lower surface of the fourth plastic sheet, and connected to the corresponding fourth connection plug;
a fifth plastic sheet having a lower surface connected to the upper surface of the third plastic sheet, and formed with at least one fifth opening;
a third circuit pattern layer embedded in an upper surface of the fifth plastic sheet, wherein the third circuit pattern layer includes a third circuit pattern and at least one third connection pad in form of annular, wherein the fifth opening is in alignment with center of the third connection pad;
at least one fifth connection plug made from of the electrically conductive material, wherein the fifth connection plug fills the fifth opening in such a manner to connected the third connection pad with corresponding second interlayer connection pad;
a sixth plastic sheet having an upper surface connected to the lower surface of the fourth plastic sheet, and formed with at least one sixth opening;
a fourth circuit pattern layer embedded in a lower surface of the fourth plastic sheet, wherein the fourth circuit pattern layer includes a fourth circuit pattern and at least one fourth connection pad in form of annular, wherein the sixth opening is in alignment with center of the fourth connection pad; and
at least one sixth connection plug made from of the electrically conductive material, wherein the sixth connection plug fills the sixth opening in such a manner to connected the fourth connection pad with corresponding third interlayer connection pad,
wherein each of the second interlayer connection pad and the third interlayer connection pad has a width of 40 to 100 μm.

5. The multilayer substrate structure as claimed in claim 4, further comprising a third solder mask and a fourth solder mask, wherein the third solder mask is provided on the upper surface of the fifth plastic sheet to cover the third circuit pattern and part of the third connection pad, and the fourth solder mask is provided on the lower surface of the sixth plastic sheet to cover the fourth circuit pattern and part of the fourth connection pad.
